(19) United States
(12) Patent Application Publication
(10) Pub. No.: US 2026/0177596 A1
(43) Pub. Date: Jun. 25, 2026

(54) METHOD OF CONNECTING S-PARAMETERS, COMPUTER PROGRAM FOR PERFORMING THE SAME, AND S-PARAMETERS CONNECTING DEVICE

(71) Applicant: Huwin Co., Ltd., Seongnam-si (KR)

(72) Inventors: Jaeyong CHO, Seoul (KR); Seung II JEUNG, Seongnam-si (KR)

(21) Appl. No.: 19/073,379

(22) Filed: Mar. 7, 2025

(30) Foreign Application Priority Data
Dec. 19, 2024 (KR) 10-2024-0191887

(51) Int. Cl. G01R 27/30

(52) U.S. Cl. CPC G01R 27/30

(57) ABSTRACT

Disclosed is a method of connecting S-parameters, which connects a first S-parameter and a second S-parameter having different frequency ranges and frequency points, which includes: generating a first preprocessing S-parameter by adding an additional frequency point corresponding to a frequency point of the second S-parameter to the first S-parameter; generating a second preprocessing S-parameter by adding an additional frequency point corresponding to a frequency point of the first S-parameter to the second S-parameter; and generating connected S-parameters by connecting the first preprocessing S-parameter and the second preprocessing S-parameter having the same frequency range and the same frequency point array.

### CROSS-REFERENCE TO RELATED APPLICATION

This application claims priority to and the benefit of Korean Patent Application No. 10-2024-0191887 filed with the Korean Intellectual Property Office on Dec. 19, 2024, the entire contents of which are incorporated herein by reference.

### BACKGROUND

### (a) Field

Embodiments of the present invention relates to a method of connecting S-parameters, a computer program for performing the same, and an S-parameters connecting device.

### (b) Description of the Related Art

In general, S-parameters represent characteristics of an electrical network. The S-parameters can be applied to various designs such as a communication system, an integrated circuit, a printed circuit board, a microwave circuit, a wireless frequency circuit, etc.

The S-parameters are an indicator indicating frequency characteristics for electrical devices (parts) such as an active device, a passive device, etc. The S-parameters of the electrical device can be extracted through a 3D electromagnetic simulation. Alternatively, the S-parameters of the electrical device can be measured by using a vector network analyzer.

In order to analyze characteristics of an entire system including multiple electrical devices, the S-parameters of the electrical devices constituting the entire system should be connected. However, the S-parameters of the electrical devices can have different frequency ranges and frequency points. When the S-parameters are connected by a frequency range and a frequency point which are arbitrarily set, an error occurs (accuracy is reduced), and as a result, accuracy of analysis of the characteristics of the entire system is reduced.

### SUMMARY

Embodiments of the present invention attempts to provide a method of connecting S-parameters, a computer program for performing the same, and an S-parameters connecting device, which can minimize accuracy reduction in a connection between S-parameters having different frequency ranges and frequency points.

An exemplary embodiment of the present invention provides a method of connecting S-parameters, which connects a first S-parameter and a second S-parameter having different frequency ranges and frequency points, which includes: generating a first preprocessing S-parameter by adding an additional frequency point corresponding to a frequency point of the second S-parameter to the first S-parameter; generating a second preprocessing S-parameter by adding an additional frequency point corresponding to a frequency point of the first S-parameter to the second S-parameter; and generating connected the S-parameters by connecting the first preprocessing S-parameter and the second preprocessing S-parameter having the same frequency range and the same frequency point array.

The method may further include defining a frequency range for connecting the S-parameters as a minimum frequency point and a maximum frequency point among all frequency points constituting the first S-parameter and the second S-parameter.

An additional frequency point corresponding to the frequency point of the second S-parameter may be added to the first S-parameter by interpolation or extrapolation, and an additional frequency point corresponding to the frequency point of the first S-parameter may be added to the second S-parameter by interpolation or extrapolation.

The method of connecting S-parameters may further include defining a common range in which the frequency range of the first S-parameter and the frequency range of the second S-parameter are overlapped with each other as a frequency range for connecting the S-parameters.

The additional frequency point corresponding to the frequency point of the second S-parameter may be added to the first S-parameter by interpolation within the frequency range for connecting the S-parameter, and the additional frequency point corresponding to the frequency point of the first S-parameter may be added to the second S-parameter by interpolation within the frequency range for connecting the S-parameter.

When the frequency point of the first S-parameter is already present in the same frequency point as the frequency point of the second S-parameter, the additional frequency point may not be generated in a corresponding frequency of the first S-parameter, and when the frequency point of the second S-parameter is already present in the same frequency point as the frequency point of the first S-parameter, the additional frequency point may not be generated in a corresponding frequency of the second S-parameter.

Another exemplary embodiment of the present invention provides a computer program for performing a method of connecting S-parameters, which connects a first S-parameter and a second S-parameter having different frequency ranges and frequency points, which includes: generating a first preprocessing S-parameter by adding an additional frequency point corresponding to a frequency point of the second S-parameter to the first S-parameter; generating a second preprocessing S-parameter by adding an additional frequency point corresponding to a frequency point of the first S-parameter to the second S-parameter; and generating connected S-parameters by connecting the first preprocessing S-parameter and the second preprocessing S-parameter having the same frequency range and the same frequency point array.

Yet another exemplary embodiment of the present invention provides a method of connecting S-parameters, which includes: acquiring N S-parameters; generating a frequency point union in which frequency points of a k-th S-parameter and frequency points of a k+1-th S-parameter are sorted; generating a k-th preprocessing S-parameter by resampling the frequency points of the k-th S-parameter in response to frequency points of the frequency point union; generating a k+1-th preprocessing S-parameter by resampling the frequency points of the k+1-th S-parameter in response to the frequency points of the frequency point union; and generating connected S-parameters by connecting the k-th preprocessing S-parameter and the k+1-th preprocessing S-parameter having the same frequency range and the same frequency point array.

When the number of connection times, k of the S-parameters of generating the connected S-parameters is smaller than (N−1), increasing the k by 1, setting the connected S-parameters to a k S-parameter, and then generating the frequency point union, generating the k-th preprocessing S-parameter, generating the k+1-th preprocessing S-parameter, and generating connected S-parameters by connecting the k-th preprocessing S-parameter and the k+1-th preprocessing S-parameter may be repeatedly performed.

The method of connecting S-parameters may further include when the k becomes (N−1), outputting connected S-parameters which are finally generated as all S-parameters.

The frequency point union includes all frequency points of the k-th S-parameter and all frequency points of the k+1-th S-parameter.

A frequency point having a smaller frequency among a minimum frequency point of the k-th S-parameter and a minimum frequency point of the k+1-th S-parameter may be set as a minimum frequency point of the frequency point union, and a frequency point having a larger frequency among a maximum frequency point of the k-th S-parameter and a maximum frequency point of the k+1-th S-parameter may be set as a maximum frequency point of the frequency point union.

A common range in which the frequency range of the k-th S-parameter and the frequency range of the k+1-th S-parameter are overlapped with each other may be set as a frequency range of the frequency point union.

A frequency point having a larger frequency among the minimum frequency point of the k-th S-parameter and the minimum frequency point of the k+1-th S-parameter may be set as a minimum frequency point of the frequency point union, and a frequency point having a smaller frequency among a maximum frequency point of the k-th S-parameter and a maximum frequency point of the k+1-th S-parameter may be set as a maximum frequency point of the frequency point union.

An additional frequency point may be added to the k-th S-parameter in response to a frequency point which is included in the k+1-th S-parameter, but not included in the k-th S-parameter to generate the k-th preprocessing S-parameter, and an additional frequency point may be added to the k+1-th S-parameter in response to a frequency point which is included in the k-th S-parameter, but not included in the k+1-th S-parameter to generate the k+1-th preprocessing S-parameter.

Still yet another exemplary embodiment of the present invention provides an S-parameters connecting device which includes: an S-parameter storage storing N S-parameters for electrical devices constituting an entire system; a preprocessing S-parameter generator generating a frequency point union in which frequency points of a k-th S-parameter and frequency points of a k+1-th S-parameter are sorted, generating a k-th preprocessing S-parameter by resampling the frequency points of the k-th S-parameter in response to frequency points of the frequency point union, generating a k+1-th preprocessing S-parameter by resampling the frequency points of the k+1-th S-parameter in response to the frequency points of the frequency point union; and an S-parameter generator generating connected S-parameters by connecting the k-th preprocessing S-parameter and the k+1-th preprocessing S-parameter having the same frequency range and the same frequency point array.

The connected S-parameter generator may increase the k by 1, set the connected S-parameters to a k S-parameter, and deliver the set k-th S-parameter to the preprocessing S-parameter generator when the number of connection times, k of the S-parameters of generating the connected S-parameters is smaller than (N−1), the preprocessing S-parameter generator may repeatedly perform the process of generating the frequency point union, the process of the k-th preprocessing S-parameter, and the process of generating the k+1-th preprocessing S-parameter, and the connected S-parameter generator may repeatedly perform the process of generating the connected S-parameters by connecting a k-th preprocessing S-parameter and a k+1-th preprocessing S-parameter delivered again from the preprocessing S-parameter generator.

When the k becomes (N−1), the connected S-parameter generator may output connected S-parameters which are finally generated as all S-parameters.

The frequency point union includes all frequency points of the k-th S-parameter and all frequency points of the k+1-th S-parameter.

The frequency point union may be set as a common range in which the frequency range of the k-th S-parameter and the frequency range of the k+1-th S-parameter are overlapped with each other.

According to exemplary embodiment of the present invention, a method of connecting S-parameters, a computer program for performing the same, and an S-parameters connecting device can minimize accuracy reduction in a connection between S-parameters having different frequency ranges and frequency points.

### BRIEF DESCRIPTION OF THE DRAWINGS

FIG. 1 illustrates a connection of a first S-parameter and a second S-parameter for describing a method of connecting S-parameters according to an exemplary embodiment of the present invention.

FIG. 2 illustrates different frequency ranges and frequency points of the first S-parameter and the second S-parameter for describing the method of connecting S-parameters according to an exemplary embodiment of the present invention.

FIG. 3 is a flowchart illustrating the method of connecting S-parameters according to an exemplary embodiment of the present invention.

FIG. 4 illustrates generation of a first preprocessing S-parameter and a second preprocessing S-parameter in the method of connecting S-parameters according to an exemplary embodiment of the present invention.

FIG. 5 is a flowchart illustrating the method of connecting S-parameters according to an exemplary embodiment of the present invention.

FIG. 6 illustrates generation of a first preprocessing S-parameter and a second preprocessing S-parameter in a method of connecting S-parameters according to another exemplary embodiment of the present invention.

FIG. 7 is a block diagram illustrating an S-parameters connecting device according to an exemplary embodiment of the present invention.

FIG. 8 is a flowchart illustrating a method of connecting N S-parameters according to an exemplary embodiment of the present invention.

FIG. 9 illustrates one example of a method of generating a frequency point union in the method of connecting N S-parameters according to an exemplary embodiment of the present invention.

FIG. 10 illustrates another example of the method of generating a frequency point union in the method of connecting N S-parameters according to an exemplary embodiment of the present invention.

FIG. 11 illustrates one example of a resampling method of a frequency point in the method of connecting N S-parameters according to an exemplary embodiment of the present invention.

FIG. 12 illustrates another example of the resampling method of a frequency point in the method of connecting N S-parameters according to an exemplary embodiment of the present invention.

FIG. 13 illustrates one example of connecting eight 2-port S-parameters in series.

FIG. 14 illustrates a simulation result of eight 2-port S-parameters with a frequency range and a frequency point which are arbitrarily set in series.

FIG. 15 illustrates a simulation result of connecting eight 2-port S-parameters in series according to the method of connecting N S-parameters according to an exemplary embodiment of the present invention.

### DETAILED DESCRIPTION

Hereinafter, an exemplary embodiment of the present disclosure will be described more fully hereinafter with reference to the accompanying drawings so as to be easily implemented by those skilled in the art. The present disclosure may be implemented in various different forms and is not limited to exemplary embodiments described herein.

A part irrelevant to the description will be omitted to clearly describe the present disclosure, and the same elements will be designated by the same reference numerals throughout the specification.

In addition, unless explicitly described to the contrary, the word “comprise”, and variations such as “comprises” or “comprising”, will be understood to imply the inclusion of stated elements but not the exclusion of any other elements.

Hereinafter, a method of connecting multiple S-parameters having different frequency ranges and frequency points will be described with reference to drawings. The method of connecting S-parameters may be implemented as a computing device, a computer program which is enabled to be performed by the computing device, a storage medium which may store the computer program which is enabled to be performed by the computing device, etc.

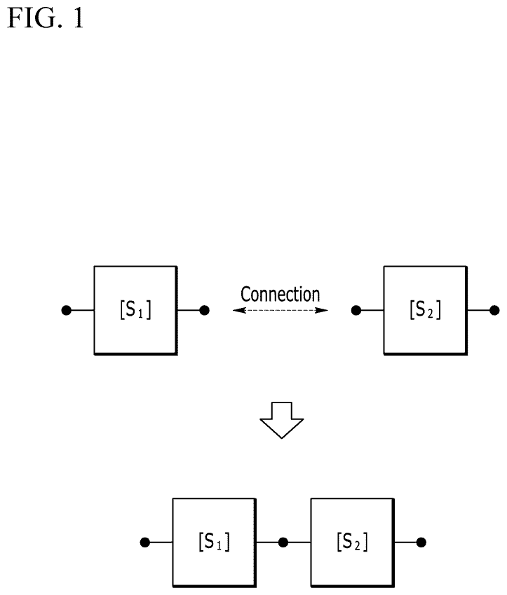

First, a method of connecting a first S-parameter and a second S-parameter having different frequency ranges and frequency points are described with reference to FIGS. 1 to 6. Hereinafter, a 2-port S-parameter is described as an example.

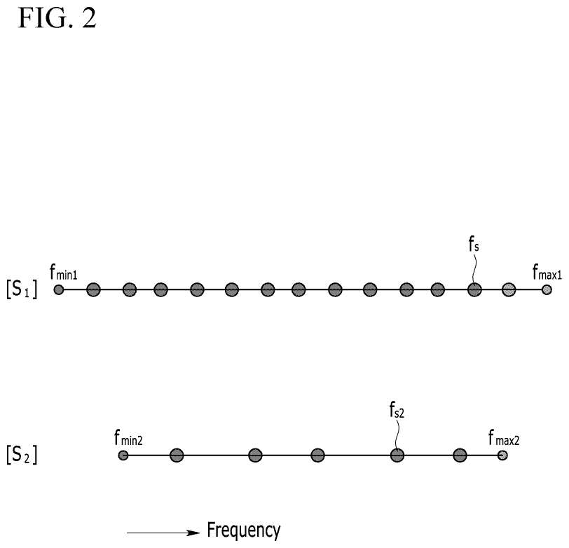

FIG. 1 illustrates a connection of a first S-parameter and a second S-parameter for describing a method of connecting S-parameters according to an exemplary embodiment of the present invention. FIG. 2 illustrates different frequency ranges and frequency points of the first S-parameter and the second S-parameter for describing the method of connecting S-parameters according to an exemplary embodiment of the present invention.

Referring to FIGS. 1 and 2, a first S-parameter S₁ and a second S-parameter S₂ may be S-parameters of an active device or a passive device. The first S-parameter S₁ and the second S-parameter S₂ may be S-parameters of electrical devices constituting an entire system including multiple electrical devices.

The first S-parameter S₁ and the second S-parameter S₂ which the 2-port S-parameters may include a first port (input port) and a second port (output port), respectively. A connection of the first S-parameter S₁ and the second S-parameter S₂ may mean a connection of a second port of the first S-parameter S₁ and a first port of the second S-parameter S₂.

The first S-parameter S₁ may include a plurality of frequency points fs₁. Each of the plurality of frequency points fs₁ may include actual data of the electrical device. The frequency range of the first S-parameter S₁ may be defined as a range between a minimum frequency point fₘᵢₙ₁ and a maximum frequency point fₘₐₓ₁ in the plurality of frequency points fs₁ constituting the first S-parameter S₁.

The second S-parameter S₂ may include a plurality of frequency points fs₂. Each of the plurality of frequency points fs₂ may include the actual data of the electrical device. The frequency range of the second S-parameter S₂ may be defined as a range between a minimum frequency point fₘᵢₙ₂ and a maximum frequency point fₘₐₓ₂ in the plurality of frequency points fs₂ constituting the second S-parameter S₂.

The minimum frequency point fₘᵢₙ₁ of the first S-parameter S₁ may be different from the minimum frequency point fₘᵢₙ₂ of the second S-parameter S₂. The maximum frequency point fₘₐₓ₁ of the first S-parameter S₁ may be different from the maximum frequency point fₘₐₓ₂ of the second S-parameter S₂. The frequency range of the first S-parameter S₁ may be different from the frequency range of the second S-parameter S₂. In addition, an interval between the plurality of frequency points fs₁ of the first S-parameter S₁ may be different from an interval between the plurality of frequency points fs₂ of the second S-parameter S₂. The plurality of frequency points fs₁ constituting the first S-parameter S₁ may not coincide with the plurality of frequency points fs₂ constituting the second S-parameter S₂. That is, the first S-parameter S₁ and the second S-parameter S₂ have different frequency ranges and frequency points.

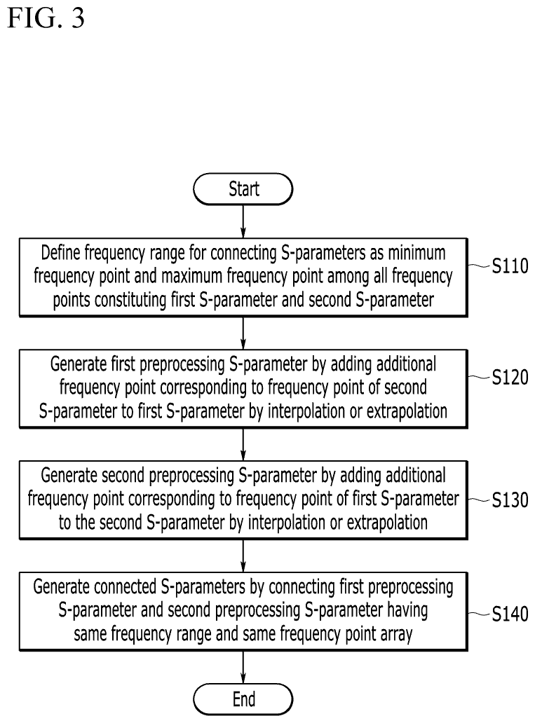

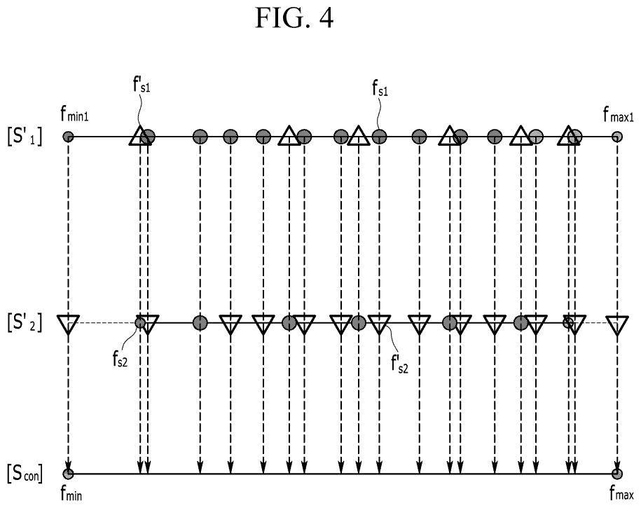

As illustrated in FIGS. 1 and 2, an exemplary embodiment of the method of connecting the first S-parameter S₁ and the second S-parameter S₂ having different frequency ranges and frequency points is described with reference to FIGS. 3 and 4.

FIG. 3 is a flowchart illustrating the method of connecting S-parameters according to an exemplary embodiment of the present invention. FIG. 4 illustrates generation of a first preprocessing S-parameter and a second preprocessing S-parameter in the method of connecting S-parameters according to an exemplary embodiment of the present invention.

Referring to FIGS. 3 and 4, a frequency range for connecting the S-parameters to the minimum frequency point and the maximum frequency point among all frequency points fs₁ and fs₂ constituting the first S-parameter S₁ and the second S-parameter S₂ may be defined (S110). In other words, a frequency point having a smaller frequency between the minimum frequency point fₘᵢₙ₁ of the first S-parameter S₁ and the minimum frequency point fₘᵢₙ₂ of the second S-parameter S₂ may become a minimum frequency point fₘᵢₙ of the frequency range for connecting the S-parameter. In addition, a frequency point having a larger frequency between the maximum frequency point fₘₐₓ₁ of the first S-parameter S₁ and the maximum frequency point fₘₐₓ₂ of the second S-parameter S₂ may become a maximum frequency point fmax of the frequency range for connecting the S-parameters. As an example, in an exemplary embodiment in which the frequency range of the second S-parameter S₂ is included in the frequency range of the first S-parameter S₁, a range between the minimum frequency point fₘᵢₙ₁ and the maximum frequency point fₘₐₓ₁ of the first S-parameter S₁ may be defined as the frequency range for connecting the S-parameters.

An additional frequency point f′s₁ corresponding to the frequency point fs₂ of the second S-parameter S₂ is added to the first S-parameter S₁ by interpolation or extrapolation to generate a first preprocessing S-parameter S′₁ (S120). That is, in the first S-parameter S₁, the additional frequency point f′s₁ may be added to the same frequency as the frequency point fs₂ of the second S-parameter S₂. A value of the additional frequency point f′s₁ may be estimated by interpolation or extrapolation in the first S-parameter S₁. When the frequency point fs₁ of the first S-parameter S₁ is already present in the same frequency as the frequency point fs₂ of the second S-parameter S₂, an additional frequency point is not generated in a corresponding frequency of the first S-parameter S₁.

An additional frequency point f′s₂ corresponding to the frequency point fs₁ of the first S-parameter S₁ is added to the second S-parameter S₂ by interpolation or extrapolation to generate a second preprocessing S-parameter S′₂ (S130). That is, in the second S-parameter S₂, the additional frequency point f′s₂ may be added to the same frequency as the frequency point fs₁ of the first S-parameter S₁. A value of the additional frequency point f′s₂ may be estimated by interpolation or extrapolation in the second S-parameter S₂. When the frequency point fs₂ of the second S-parameter S₂ is already present in the same frequency as the frequency point fs₁ of the first S-parameter S₁, an additional frequency point is not generated in a corresponding frequency of the second S-parameter S₂.

The first preprocessing S-parameter S′₁ and the second preprocessing S-parameter S′₂ have the same frequency range and the same frequency point array. An S-parameter S_{con} may be generated, which is connected by connecting the first preprocessing S-parameter S′₁ and the second preprocessing S-parameter S′₂ (S140). At least one of values of two frequency points used for the connection for each frequency point of the connected S-parameter S_{con} includes actual data. That is, the frequency point fs₁ including actual data of the first S-parameter S₁ and the additional frequency point f′s₂ including an estimated value of the second S-parameter S₂ may be connected. Alternatively, the additional frequency point f′s₁ including an estimated value of the first S-parameter S₁ and the frequency point fs₂ including actual data of the second S-parameter S₂ may be connected. Alternatively, the frequency point fs₁ including the actual data of the first S-parameter S₁ and the frequency point fs₂ including the actual data of the second S-parameter S₂ may be connected.

As at least one of the values of two frequency points used for the connection for each frequency point includes the actual data, an error which may occur by interpolation or extrapolation and accuracy reduction of the connected S-parameter S_{con} may be minimized in a connection process of the first S-parameter S₁ and the second S-parameter S₂.

As an example, when the frequency range and the frequency point for connecting the S-parameters are arbitrarily set, the frequency point estimated by interpolation or extrapolation in the first S-parameter S₁ and the frequency point estimated by interpolation or extrapolation in the second S-parameter S₂ may be connected according to the frequency range and the frequency point which are arbitrarily set. When the frequency points estimated by interpolation or extrapolation are connected, the error which occurs by interpolation or extrapolation is doubled to further reduce the accuracy of the connected S-parameter.

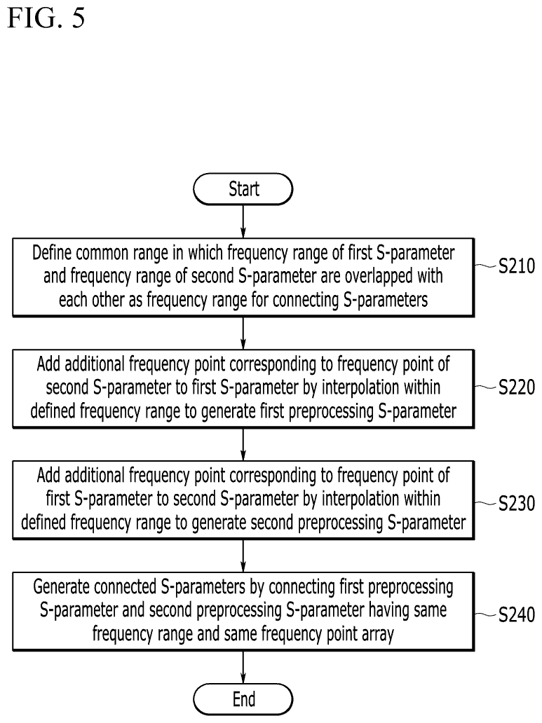

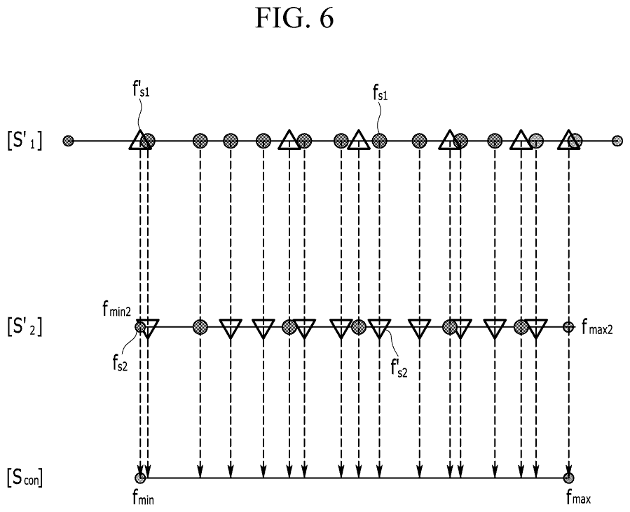

As illustrated in FIGS. 1 and 2, another exemplary embodiment of the method of connecting the first S-parameter S₁ and the second S-parameter S₂ having different frequency ranges and frequency points is described with reference to FIGS. 5 and 6.

FIG. 5 is a flowchart illustrating the method of connecting S-parameters according to an exemplary embodiment of the present invention. FIG. 6 illustrates generation of a first preprocessing S-parameter and a second preprocessing S-parameter in a method of connecting S-parameters according to another exemplary embodiment of the present invention.

Referring to FIGS. 5 and 6, a common range in which the frequency range of the first S-parameter S₁ and the frequency range of the second S-parameter S₂ are overlapped with each other may be defined as the frequency range for connecting the S-parameters (S210). In other words, a frequency point having a larger frequency between the minimum frequency point fₘᵢₙ₁ of the first S-parameter S₁ and the minimum frequency point fₘᵢₙ₂ of the second S-parameter S₂ may become a minimum frequency point fₘᵢₙ of the frequency range for connecting the S-parameter. In addition, a frequency point having a smaller frequency between the maximum frequency point fₘₐₓ₁ of the first S-parameter S₁ and the maximum frequency point fₘₐₓ₂ of the second S-parameter S₂ may become a maximum frequency point fmax of the frequency range for connecting the S-parameters. As an example, in an exemplary embodiment in which the frequency range of the second S-parameter S₂ is included in the frequency range of the first S-parameter S₁, a range between the minimum frequency point fₘᵢₙ₂ and the maximum frequency point fₘₐₓ₂ of the second S-parameter S₂ may be defined as the frequency range for connecting the S-parameters.

Within the defined frequency range, an additional frequency point f′s₁ corresponding to the frequency point fs₂ of the second S-parameter S₂ is added to the first S-parameter S₁ by interpolation to generate a first preprocessing S-parameter S′₁ (S220). That is, in the first S-parameter S₁, the additional frequency point f′s₁ may be added to the same frequency as the frequency point fs₂ of the second S-parameter S₂ within the defined frequency range. A value of the additional frequency point f′s₁ may be estimated by interpolation in the first S-parameter S₁. When the frequency point fs₁ of the first S-parameter S₁ is already present in the same frequency as the frequency point fs₂ of the second S-parameter S₂, an additional frequency point is not generated in a corresponding frequency.

Within the defined frequency range, an additional frequency point f′s₂ corresponding to the frequency point fs₁ of the first S-parameter S₁ is added to the second S-parameter S₂ by interpolation to generate a second preprocessing S-parameter S′₂ (S230). That is, in the second S-parameter S₂, the additional frequency point f′s₂ may be added to the same frequency as the frequency point fs₁ of the first S-parameter S₁ within the defined frequency range. A value of the additional frequency point f′s₂ may be estimated by interpolation in the second S-parameter S₂. When the frequency point fs₂ of the second S-parameter S₂ is already present in the same frequency as the frequency point fs₁ of the first S-parameter S₁, an additional frequency point is not generated in a corresponding frequency.

The first preprocessing S-parameter S′₁ and the second preprocessing S-parameter S′₂ have the same frequency range and the same frequency point array. An S-parameter S_{con} may be generated, which is connected by connecting the first preprocessing S-parameter S′₁ and the second preprocessing S-parameter S′₂ (S240). As described in the exemplary embodiment of FIGS. 3 and 4, at least one of values of two frequency points used for the connection for each frequency point of the connected S-parameter S_{con} includes actual data. The error which may occur by interpolation may be minimized, and accuracy reduction of the connected S-parameter S_{con} may be minimized in the connection process of the first S-parameter S₁ and the second S-parameter S₂.

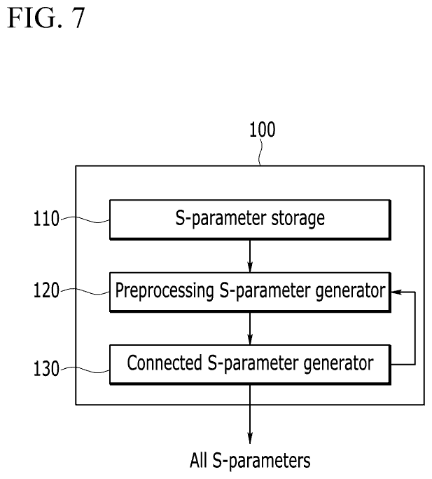

Now, a device and a method of connecting S-parameters, which may connect a plurality of (N) S-parameters are described with reference to FIGS. 7 to 15.

FIG. 7 is a block diagram illustrating an S-parameters connecting device according to an exemplary embodiment of the present invention.

Referring to FIG. 7, an S-parameters connecting device 100 may include an S-parameter storage 110, a preprocessing S-parameter generator 120, and a connected S-parameter generator 130. The S-parameters connecting device 100 may be implemented as a computing device, a computer program which is enabled to be performed by the computing device, a storage medium which may store the computer program which is enabled to be performed by the computing device, etc. The S-parameters connecting device 100 may be included in a device which may estimate or measure the S-parameter of the electrical device.

The S-parameter storage 110 may store a plurality of (N) S-parameters for the electrical devices constituting the entire system. The S-parameter storage 110 may receive and store S-parameters of respective electrical devices extracted through a 3D electromagnetic simulation. The S-parameter storage 110 may receive and store S-parameters of respective electrical devices measured by using a vector network analyzer.

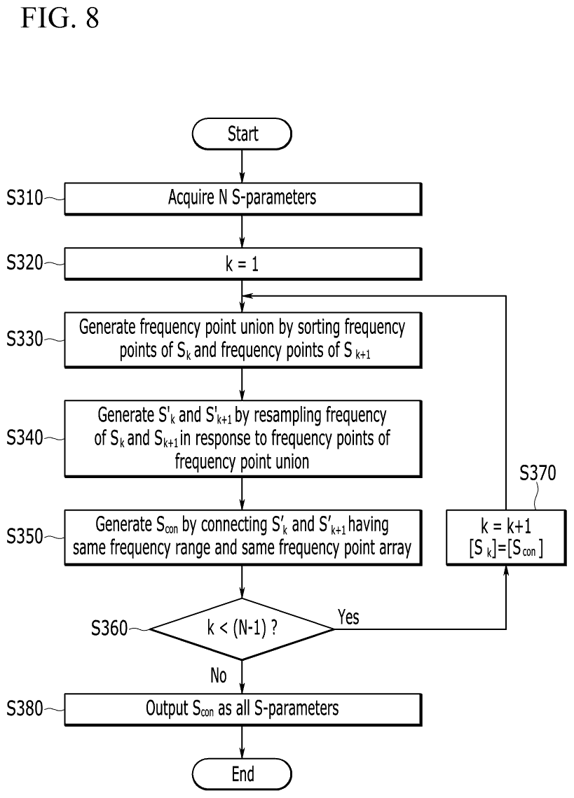

The preprocessing S-parameter generator 120 receives a plurality of S-parameters for the electrical devices constituting the entire system from the S-parameter storage 110 to generate a preprocessing S-parameter. The preprocessing S-parameter generator 120 may generate the preprocessing S-parameter by the method described above in the exemplary embodiment of FIGS. 3 and 4. Alternatively, the preprocessing S-parameter generator 120 may generate the preprocessing S-parameter by the method described above in the exemplary embodiment of FIGS. 5 and 6. Alternatively, the preprocessing S-parameter generator 120 may generate the preprocessing S-parameter by a method described below with reference to FIG. 8.

The connected S-parameter generator 130 may generate connected S-parameters by connecting two preprocessing S-parameters received from the preprocessing S-parameter generator 120.

In order to connect the plurality of (N) S-parameters, the connected S-parameter generator 130 may deliver the connected S-parameters to the preprocessing S-parameter generator 120. The preprocessing S-parameter generator 120 may generate the preprocessing S-parameter for the delivered connected S-parameters and the S-parameters to be connected thereto, and deliver the generated preprocessing S-parameter to the connected S-parameter generator 130. The preprocessing S-parameter generator 120 and the connected S-parameter generator 130 may repeat the generation of the preprocessing S-parameter and the generation of the connected S-parameters (N−1) times until all of N S-parameters are connected. The connected S-parameter generator 130 may output the connected S-parameters which are finally generated as all S-parameters when all of N S-parameters are connected.

FIG. 8 is a flowchart illustrating a method of connecting N S-parameters according to an exemplary embodiment of the present invention.

Referring to FIG. 8, N S-parameters for the electrical devices constituting the entire system may be acquired (S310). That is, S-parameters S₁, S₂, . . . , S_{N} may be acquired. N S-parameters may be extracted through the 3D electromagnetic simulation or measured by using the vector network analyzer. N S-parameters may be stored in the S-parameter storage 110. N represents an integer of 2 or more.

The number of connection times (or connection turns) of the S-parameters, k may be set to 1 (S320). That is, when the connection of N S-parameters is started, k may be set to 1. k represents an integer of 1 or more.

A frequency point union may be generated, in which frequency points of a k-th S-parameter Sₖ and frequency points of a k+1-th S-parameter Sₖ₊₁ (S330). That is, the preprocessing S-parameter generator 120 may confirm frequency ranges and frequency points of the k-th S-parameter Sₖ and confirm frequency ranges and frequency points of the k+1-th S-parameter Sₖ₊₁. The preprocessing S-parameter generator 120 may generate the frequency point union by sorting the frequency points of the k-th S-parameter Sₖ and the frequency points of the k+1-th S-parameter Sₖ₊₁ in an ascending order.

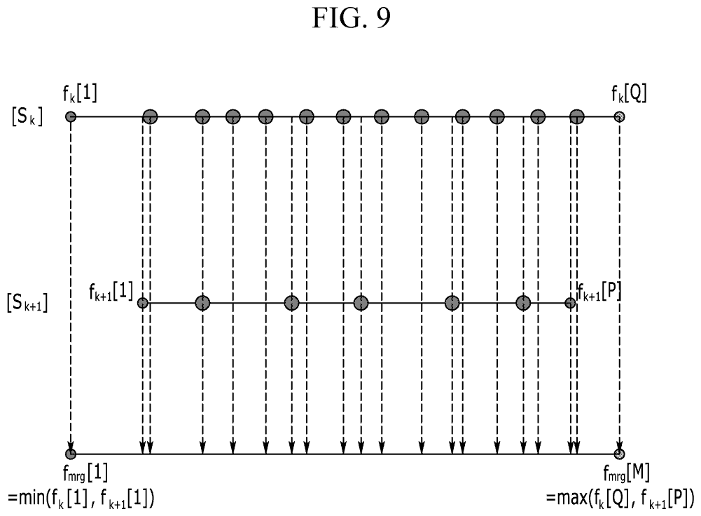

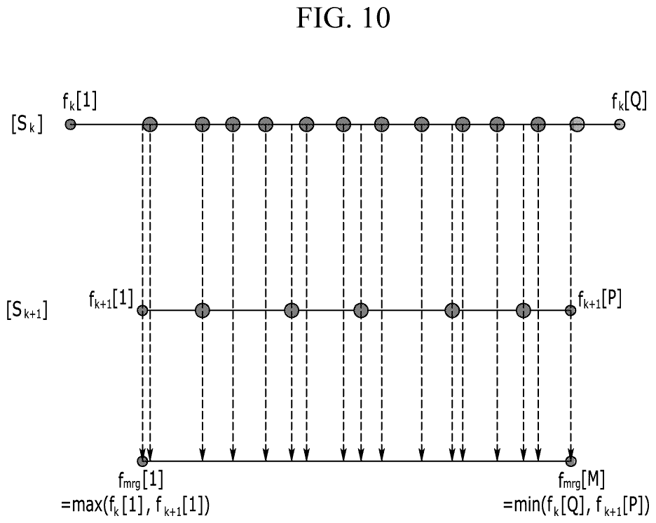

Referring to FIGS. 9 and 10, a method for generating the frequency point union is described in more detail.

FIG. 9 illustrates one example of a method of generating a frequency point union in the method of connecting N S-parameters according to an exemplary embodiment of the present invention.

Referring to FIG. 9, it is assumed that the frequency point of the k-th S-parameter Sₖ is fₖ[1], . . . , fₖ[Q] and the frequency point of the k+1-th S-parameter Sₖ₊₁ is fₖ₊₁[1], . . . , fₖ₊₁[P]. In this case, Q represents the number of frequency points included in the k-th S-parameter Sₖ, and P represents the number of frequency points included in the k+1-th S-parameter Sₖ₊₁.

The preprocessing S-parameter generator 120 may generate a frequency point union including all frequency points of the k-th S-parameter Sₖ and all frequency points of the k+1-th S-parameter Sₖ₊₁.

More specifically, the preprocessing S-parameter generator 120 may set a frequency point having a smaller frequency between a minimum frequency point fₖ[1] of the k-th S-parameter Sₖ and a minimum frequency point fₖ₊₁[1] of the k+1-th S-parameter Sₖ₊₁ to a minimum frequency point f_{mrg}[1] of the frequency point union. That is, f_{mrg}[1]=min (fₖ[1], fₖ₊₁[1]).

In addition, the preprocessing S-parameter generator 120 may set a frequency point having a larger frequency between a maximum frequency point fₖ[Q] of the k-th S-parameter Sₖ and a maximum frequency point fₖ₊₁[P] of the k+1-th S-parameter Sₖ₊₁ to a maximum frequency point f_{mrg}[M] of the frequency point union. That is, f_{mrg}[M]=max (fₖ[Q], fₖ₊₁[P]).

The frequency range of the frequency point union may be set to a range of f_{mrg}[1] to f_{mrg}[M].

The preprocessing S-parameter generator 120 may generate the frequency point union f_{mrg} by sorting the frequency points of the k-th S-parameter Sₖ and the frequency points of the k+1-th S-parameter Sₖ₊₁ in the ascending order. That is, f_{mrg}=sort [fₖ U fₖ₊₁].

FIG. 10 illustrates another example of the method of generating a frequency point union in the method of connecting N S-parameters according to an exemplary embodiment of the present invention.

Referring to FIG. 10, as a difference from the exemplary embodiment of FIG. 9, the preprocessing S-parameter generator 120 may set a common range in which the frequency range of the k-th S-parameter Sₖ and the frequency ranges of the k+1-th S-parameter Sₖ₊₁. are overlapped with each other as the frequency range of the frequency point union.

More specifically, the preprocessing S-parameter generator 120 may set a frequency point having a larger frequency between a minimum frequency point fₖ[1] of the k-th S-parameter Sₖ and a minimum frequency point fₖ₊₁[1] of the k+1-th S-parameter Sₖ₊₁ to a minimum frequency point f_{mrg}[1] of the frequency point union. That is, f_{mrg}[1]=max (fₖ[1], fₖ₊₁[1]).

In addition, the preprocessing S-parameter generator 120 may set a frequency point having a smaller frequency between a minimum? frequency point fₖ[Q] of the k-th S-parameter Sₖ and a maximum frequency point fₖ₊₁[P] of the k+1-th S-parameter Sₖ₊₁ to a maximum frequency point f_{mrg}[M] of the frequency point union. That is, f_{mrg}[M]=min (fₖ[Q], fₖ₊₁[P]).

The frequency range of the frequency point union may be set to a range of f_{mrg}[1] to f_{mrg}[M].

The preprocessing S-parameter generator 120 may generate the frequency point union f_{mrg} by sorting the frequency points of the k-th S-parameter Sₖ and the frequency points of the k+1-th S-parameter Sₖ₊₁ in the ascending order within the set frequency range.

Referring back to FIG. 8, by resampling the frequency points of the k-th S-parameter Sₖ and the frequency points of the k+1-th S-parameter Sₖ₊₁ in response to the frequency points of the frequency point union, a k-th preprocessing S-parameter S′k and a k+1-th preprocessing S-parameter S′ₖ₊₁ may be generated (S340). That is, the preprocessing S-parameter generator 120 may generate the k-th preprocessing S-parameter S′k by resampling the frequency points of the k-th S-parameter Sₖ in response to the frequency points of the frequency point union. In addition, the preprocessing S-parameter generator 120 may generate the k+1-th preprocessing S-parameter S′ₖ₊₁ by resampling the frequency points of the k+1-th S-parameter Sₖ₊₁ in response to the frequency points of the frequency point union.

In other words, the preprocessing S-parameter generator 120 may generate the k+1-th preprocessing S-parameter S′ₖ₊₁ by adding and resampling an additional frequency point to the k+1-th S-parameter Sₖ₊₁ in response to a frequency point which is included in the k-th S parameter Sₖ, but not included in the k+1-th S-parameter Sₖ₊₁ in the frequency point union. In addition, the preprocessing S-parameter generator 120 may generate the k-th preprocessing S-parameter S′k by adding and resampling an additional frequency point to the k-th S-parameter Sₖ in response to a frequency point which is included in the k+1-th S-parameter Sₖ₊₁, but not included in the k-th S-parameter Sₖ in the frequency point union. The additional frequency point may be added by interpolation or extrapolation.

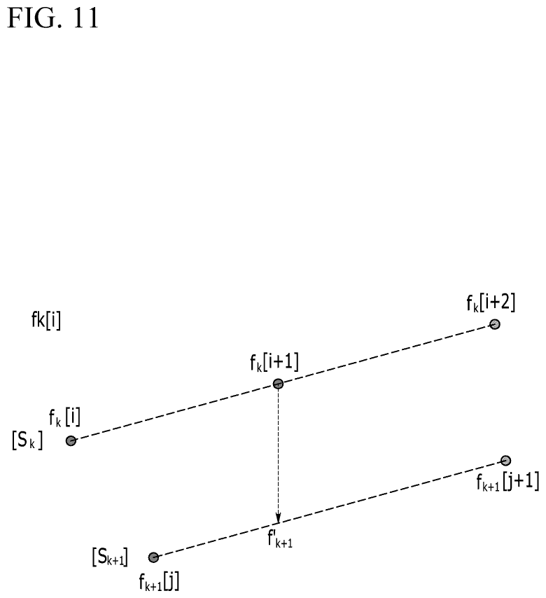

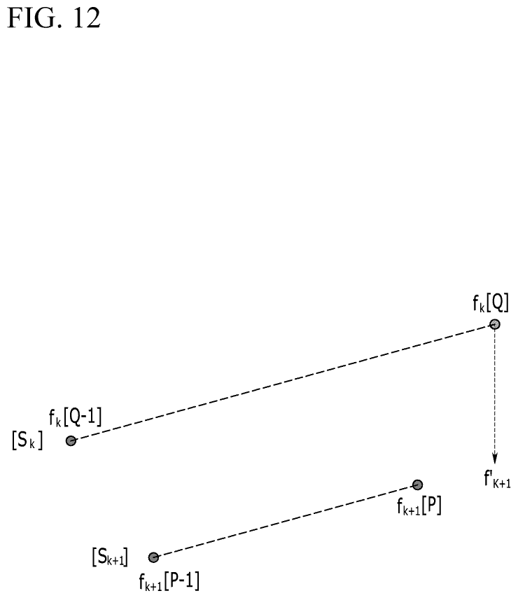

Referring to FIG. 11, a method of adding the additional frequency point by interpolation is described, and referring to FIG. 12, a method of adding the additional frequency point by extrapolation is described.

FIG. 11 illustrates one example of a resampling method of a frequency point in the method of connecting N S-parameters according to an exemplary embodiment of the present invention.

Referring to FIG. 11, a method of adding an additional frequency point f′ₖ₊₁ to the k+1-th S-parameter Sₖ₊₁ by interpolation in response to a frequency point which is included in the k-th S-parameter Sₖ, but not included in the k+1-th S-parameter Sₖ₊₁ in the frequency point union is described as an example.

The S-parameter is a complex number. Therefore, the preprocessing S-parameter generator 120 may separate the S-parameter into a magnitude and a phase, and apply interpolation. Alternatively, the preprocessing S-parameter generator 120 may separate the S-parameter into a real number and an imaginary number, and apply interpolation. The interpolation may be applied as a general primary linear technique. Alternatively, the interpolation may be applied as a secondary or tertiary polynomial technique.

The additional frequency point added by a primary linear interpolation technique of size and phase formats to the k+1-th S-parameter Sₖ₊₁ in response to the frequency point fₖ[i+1] included in the k-th S parameter Sₖ may be calculated as in Equation 1.

$$\begin{matrix}\vert {S}_{k + 1} [ {f}_{k + 1} ] \vert = \frac{\vert {S}_{k + 1} [ {f}_{k + 1} [ j + 1 ] ] \vert - \vert {S}_{k + 1} [ {f}_{k + 1} [ j ] ] \vert}{{f}_{k + 1} [ j + 1 ] - {f}_{k + 1} [ j ]} ( {f}_{k + 1}^{′} - {f}_{k + 1} [ j ] ) + \vert {S}_{k + 1} [ {f}_{k + 1} [ j ] ] \vert \\ ∠ {S}_{k + 1} [ {f}_{k + 1} ] = \frac{∠ {S}_{k + 1} [ {f}_{k + 1} [ j + 1 ] ] - ∠ {S}_{k + 1} [ {f}_{k + 1} [ j ] ]}{{f}_{k + 1} [ j + 1 ] - {f}_{k + 1} [ j ]} ( {f}_{k + 1}^{′} - {f}_{k + 1} [ j ] ) + ∠ {S}_{k + 1} [ {f}_{k + 1} [ j ] ]\end{matrix} \qquad ( Equation 1 )$$

Where the additional frequency point f′ₖ₊₁ added to the k+1-th S-parameter Sₖ₊₁ is added between the frequency point fₖ₊₁[j] and the frequency point fₖ₊₁[j+1].

FIG. 12 illustrates another example of the resampling method of a frequency point in the method of connecting N S-parameters according to an exemplary embodiment of the present invention.

Referring to FIG. 12, a method of adding an additional frequency point f′ₖ₊₁ to the k+1-th S-parameter Sₖ₊₁ by extrapolation in response to a frequency point which is included in the k-th S parameter Sₖ, but not included in the k+1-th S-parameter Sₖ₊₁ in the frequency point union is described as an example. The extrapolation may be applied as a general constant technique.

The additional frequency point f′ₖ₊₁ added by a constant extrapolation technique to the k+1-th S-parameter Sₖ₊₁ in response to the frequency point fₖ[Q] included in the k-th S-parameter Sₖ may be calculated as in Equation 2.

$${S}_{k + 1} [ {f}_{k + 1}^{′} ] = {S}_{k + 1} [ {f}_{k + 1} [ P ] ] \qquad ( Equation 2 )$$

Where the additional frequency point f′ₖ₊₁ added to the k+1-th S-parameter Sₖ₊₁ is added to a frequency larger than a maximum frequency point fₖ₊₁[P] of the k+1-th S-parameter Sₖ+1.

That is, the extrapolation may be applied to an additional frequency point which deviates from the frequency range of the k+1-th S-parameter Sₖ₊₁. When the extrapolation is applied, the minimum frequency point fₖ₊₁[1] or the maximum frequency point fₖ₊₁[P] of the k+1-th S-parameter Sₖ₊₁ may be applied as a value of the additional frequency point f′ₖ₊₁.

Referring back to FIG. 8, the k-th S-preprocessing parameter S′k and the k+1-th preprocessing S-parameter S′ₖ₊₁ have the same frequency range and the same frequency point array. The connected S-parameter S_{con} may be generated by connecting the k-th preprocessing S-parameter S′ₖ and the k+1-th preprocessing S-parameter S′ₖ₊₁ (S350). That is, the connected S-parameter generator 130 may generate the connected S-parameters S_{con} by connecting the k-th S-parameter S′k and the k+1-th S-parameter S′ₖ₊₁.

The connected S-parameter generator 130 may confirm whether the number of connection times, k of the S-parameters of generating the connected S-parameters S_{con} is smaller than (N−1) (S360). This is to repeatedly generate the preprocessing S-parameter and generate the connected S-parameters (N−1) times in order to connect all N S-parameters.

When the number of connection times, k of the S-parameters is smaller than (N−1), k may be increased by (k=k+1), and the connected S-parameters S_{con} may be set to the k-th S-parameter Sₖ ([Sₖ]=[S_{con}]) (S370). That is, the connected S-parameter generator 130 increases k by 1 and sets the connected S-parameter S_{con} to the k-th S-parameter Sₖ to deliver the set k-th S-parameter Sₖ to the preprocessing S-parameter generator 120.

Thereafter, the preprocessing S-parameter generator 120 may repeatedly perform a process (S330) of generating the frequency point union by sorting the frequency points of the k-th S-parameter Sₖ and the frequency points of the k+1-th S-parameter Sₖ₊₁, and a process (S340) of generating the k-th preprocessing S-parameter S′k and the k+1-th preprocessing S-parameter S′ₖ₊₁ by resampling the frequency points of the k-th S-parameter Sₖ and the k+1-th S-parameter Sₖ₊₁ in response to the frequency points of the frequency point union. In addition, the connected S-parameter generator 130 may repeatedly perform a process (S350) of generating the connected S-parameters S_{con} by connecting the k-th S-parameter S′k and the k+1-th S-parameter S′ₖ₊₁ delivered again from the preprocessing S-parameter generator 120. As a result, one S-parameter may be further connected to the connected S-parameter S_{con}.

By such a scheme, when the generation of the preprocessing S-parameter and the generation of the connected S-parameters are repeated (N−1) times, N S-parameters may be all connected.

When the number of connection times, k of the S-parameters is not smaller than (N−1), that is, when k becomes (N−1), the connected S-parameters S_{con} which are finally generated may be output as all S-parameters. That is, the connected S-parameter generator 130 may output the connected S-parameters which are finally generated as all S-parameters. All S-parameters are the S-parameters of the entire system including multiple electrical devices.

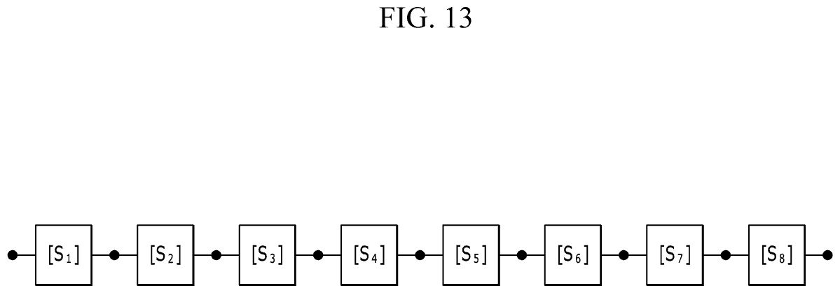

Hereinafter, a simulation result of connecting eight 2-port S-parameters in series will be described with reference to FIGS. 13 to 15.

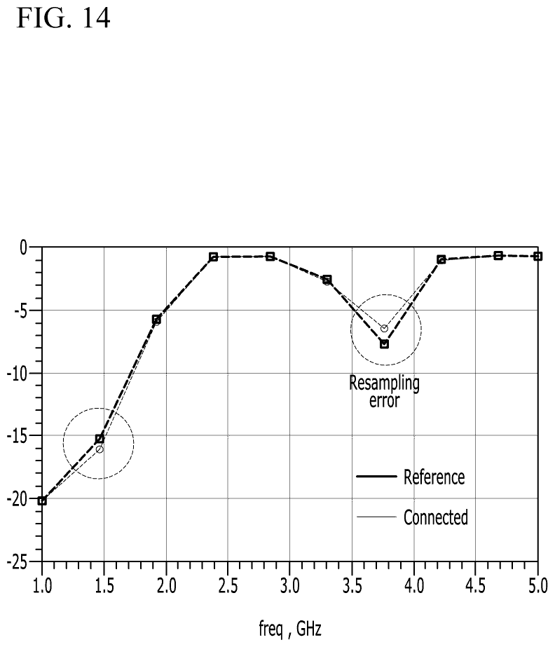

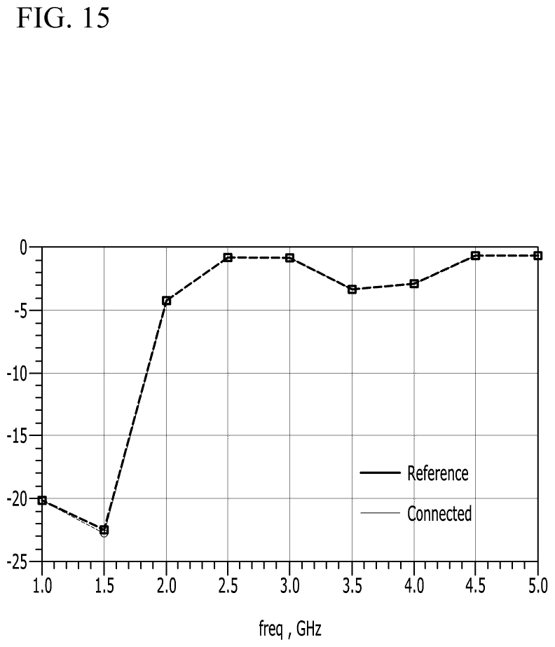

FIG. 13 illustrates one example of connecting eight 2-port S-parameters in series. FIG. 14 illustrates a simulation result of eight 2-port S-parameters with a frequency range and a frequency point which are arbitrarily set in series. FIG. 15 illustrates a simulation result of connecting eight 2-port S-parameters in series according to the method of connecting N S-parameters according to an exemplary embodiment of the present invention.

Referring to FIGS. 13 to 15, a first S-parameter S₁, a second S-parameter S₂, a third S-parameter S₃, a fourth S-parameter S₄, a fifth S-parameter S₅, a sixth S-parameter S₆, a seventh S-parameter S₇, and an eighth S-parameter S₈ are connected in series. In this case, frequency ranges of the first S-parameter S₁, the third S-parameter S₃, the fifth S-parameter S₅, and the seventh S-parameter S₇ are 1 to 5 GHZ, and intervals between the frequency points are 1 GHZ. In addition, frequency ranges of the second S-parameter S₂, the fourth S-parameter S₄, the sixth S-parameter S₆, and the eighth S-parameter S₈ are 1 to 5 GHZ, and intervals between the frequency points are 0.5 GHZ.

As a case of arbitrarily setting the frequency range and the frequency point for connecting the S-parameters, a simulation result of connecting eight 2-port S-parameters in series by setting the frequency range for connecting the S-parameters to 1 to 5 GHz and setting the intervals between the frequency points to 0.46 GHz is shown in a graph of FIG. 14. The result of connecting eight 2-port S-parameters in series by the method of connecting the S-parameters according to the exemplary embodiment of the present invention is shown in a graph of FIG. 15. Here, a reference graph shows a connection result when all of eight 2-port S-parameters include the frequency points.

In the graph of FIG. 14, it can be seen that a resampling error occurs. On the contrary, in the graph of FIG. 15, it can be seen that the resampling error barely occurs.

The drawings referred and the detailed description of the present invention disclosed up to now are just used for exemplifying the present invention and they are just used for the purpose of describing the present invention, but not used for limiting a meaning or restricting the scope of the present invention disclosed in the claims. Therefore, it will be appreciated by those skilled in the art that various modifications and other exemplary embodiments equivalent thereto can be made therefrom. Accordingly, the true technical scope of the present invention should be defined by the technical spirit of the appended claims.

What is claimed is:

1. A method of connecting S-parameters, which connects a first S-parameter and a second S-parameter having different frequency ranges and frequency points, comprising:
generating a first preprocessing S-parameter by adding an additional frequency point corresponding to a frequency point of the second S-parameter to the first S-parameter;
generating a second preprocessing S-parameter by adding an additional frequency point corresponding to a frequency point of the first S-parameter to the second S-parameter; and
generating connected S-parameters by connecting the first preprocessing S-parameter and the second preprocessing S-parameter having the same frequency range and the same frequency point array.

2. The method of claim 1, further comprising:
defining a frequency range for connecting S-parameters as a minimum frequency point and a maximum frequency point among all frequency points constituting the first S-parameter and the second S-parameter.

3. The method of claim 2, wherein:
an additional frequency point corresponding to the frequency point of the second S-parameter is added to the first S-parameter by interpolation or extrapolation, and
an additional frequency point corresponding to the frequency point of the first S-parameter is added to the second S-parameter by interpolation or extrapolation.

4. The method of claim 1, further comprising:
defining a common range in which the frequency range of the first S-parameter and the frequency range of the second S-parameter are overlapped with each other as a frequency range for connecting the S-parameters.

5. The method of claim 4, wherein:
the additional frequency point corresponding to the frequency point of the second S-parameter is added to the first S-parameter by interpolation within the frequency range for connecting the S-parameter, and
the additional frequency point corresponding to the frequency point of the first S-parameter is added to the second S-parameter by interpolation within the frequency range for connecting the S-parameter.

6. The method of claim 1, wherein:
when the frequency point of the first S-parameter is already present in the same frequency point as the frequency point of the second S-parameter, the additional frequency point is not generated in a corresponding frequency of the first S-parameter, and
when the frequency point of the second S-parameter is already present in the same frequency point as the frequency point of the first S-parameter, the additional frequency point is not generated in a corresponding frequency of the second S-parameter.

7. A computer program for performing a method of connecting S-parameters, which connects a first S-parameter and a second S-parameter having different frequency ranges and frequency points, comprising:
generating a first preprocessing S-parameter by adding an additional frequency point corresponding to a frequency point of the second S-parameter to the first S-parameter;
generating a second preprocessing S-parameter by adding an additional frequency point corresponding to a frequency point of the first S-parameter to the second S-parameter; and
generating connected S-parameters by connecting the first preprocessing S-parameter and the second preprocessing S-parameter having the same frequency range and the same frequency point array.

8. A method of connecting S-parameters, comprising:
acquiring N S-parameters;
generating a frequency point union in which frequency points of a k-th S-parameter and frequency points of a k+1-th S-parameter are sorted;
generating a k-th preprocessing S-parameter by resampling the frequency points of the k-th S-parameter in response to frequency points of the frequency point union;
generating a k+1-th preprocessing S-parameter by resampling the frequency points of the k+1-th S-parameter in response to the frequency points of the frequency point union; and
generating connected S-parameters by connecting the k-th preprocessing S-parameter and the k+1-th preprocessing S-parameter having the same frequency range and the same frequency point array.

9. The method of claim 8, wherein:
when the number of connection times, k of the S-parameters of generating the connected S-parameters is smaller than (N−1), increasing the k by 1, setting the connected S-parameters to a k S-parameter, and then generating the frequency point union, generating the k-th preprocessing S-parameter, generating the k+1-th preprocessing S-parameter, and generating connected S-parameters by connecting the k-th preprocessing S-parameter and the k+1-th preprocessing S-parameter are repeatedly performed.

10. The method of claim 9, further comprising:
when the k becomes (N−1), outputting connected S-parameters which are finally generated as all S-parameters.

11. The method of claim 8, wherein:
the frequency point union includes all frequency points of the k-th S-parameter and all frequency points of the k+1-th S-parameter.

12. The method of claim 11, wherein:
a frequency point having a smaller frequency among a minimum frequency point of the k-th S-parameter and a minimum frequency point of the k+1-th S-parameter is set as a minimum frequency point of the frequency point union, and
a frequency point having a larger frequency among a maximum frequency point of the k-th S-parameter and a maximum frequency point of the k+1-th S-parameter is set as a maximum frequency point of the frequency point union.

13. The method of claim 8, wherein:
a common range in which the frequency range of the k-th S-parameter and the frequency range of the k+1-th S-parameter are overlapped with each other as a frequency range of the frequency point union.

14. The method of claim 13, wherein:
a frequency point having a larger frequency among the minimum frequency point of the k-th S-parameter and the minimum frequency point of the k+1-th S-parameter is set as a minimum frequency point of the frequency point union, and
a frequency point having a smaller frequency among a maximum frequency point of the k-th S-parameter and a maximum frequency point of the k+1-th S-parameter is set as a maximum frequency point of the frequency point union.

15. The method of claim 8, wherein:
an additional frequency point is added to the k-th S-parameter in response to a frequency point which is included in the k+1-th S-parameter, but not included in the k-th S-parameter to generate the k-th preprocessing S-parameter, and
an additional frequency point is added to the k+1-th S-parameter in response to a frequency point which is included in the k-th S-parameter, but not included in the k+1-th S-parameter to generate the k+1-th preprocessing S-parameter.

16. An S-parameters connecting device comprising:
an S-parameter storage storing N S-parameters for electrical devices constituting an entire system;
a preprocessing S-parameter generator generating a frequency point union in which frequency points of a k-th S-parameter and frequency points of a k+1-th S-parameter are sorted, generating a k-th preprocessing S-parameter by resampling the frequency points of the k-th S-parameter in response to frequency points of the frequency point union, generating a k+1-th preprocessing S-parameter by resampling the frequency points of the k+1-th S-parameter in response to the frequency points of the frequency point union; and
an S-parameter generator generating connected S-parameters by connecting the k-th preprocessing S-parameter and the k+1-th preprocessing S-parameter having the same frequency range and the same frequency point array.

17. The S-parameters connecting device of claim 16, wherein:
the connected S-parameter generator increases the k by 1, sets the connected S-parameters to a k S-parameter, and delivers the set k-th S-parameter to the preprocessing S-parameter generator when the number of connection times, k of the S-parameters of generating the connected S-parameters is smaller than (N−1),
the preprocessing S-parameter generator repeatedly performs the process of generating the frequency point union, the process of the k-th preprocessing S-parameter, and the process of generating the k+1-th preprocessing S-parameter, and
the connected S-parameter generator repeatedly performs the process of generating the connected S-parameters by connecting a k-th preprocessing S-parameter and a k+1-th preprocessing S-parameter delivered again from the preprocessing S-parameter generator.

18. The S-parameters connecting device of claim 17, wherein:
when the k becomes (N−1), the connected S-parameter generator outputs connected S-parameters which are finally generated as all S-parameters.

19. The S-parameters connecting device of claim 16, wherein:
the frequency point union includes all frequency points of the k-th S-parameter and all frequency points of the k+1-th S-parameter.

20. The S-parameters connecting device of claim 16, wherein:
the frequency point union is set as a common range in which the frequency range of the k-th S-parameter and the frequency range of the k+1-th S-parameter are overlapped with each other.
